(19) United States
(12) Patent Application Publication
(10) Pub. No.: US 2024/0152307 A1
(43) Pub. Date: May 9, 2024

(54) FOLDABLE ELECTRONIC DEVICE AND CONTROL METHOD THEREFOR

(71) Applicant: SAMSUNG ELECTRONICS CO., LTD., Suwon-si (KR)

(72) Inventors: Joonsung HAN, Suwon-si (KR); Jinkyo CHUNG, Suwon-si (KR)

(73) Assignee: SAMSUNG ELECTRONICS CO., LTD., Suwon-si (KR)

(21) Appl. No.: 18/412,113

(22) Filed: Jan. 12, 2024

Related U.S. Application Data
(63) Continuation of application No. PCT/KR2022/008652, filed on Jun. 17, 2022.

(30) Foreign Application Priority Data
Jul. 16, 2021 (KR) 10-2021-0093619

(51) Int. Cl. G06F 3/14; G01D 5/54; G06F 3/01; G06F 3/16; H05K 5/02

(52) U.S. Cl. CPC G06F 3/14; G01D 5/54; G06F 3/016; G06F 3/167; H05K 5/0226

(57) ABSTRACT

Disclosed is an electronic device including a housing structure including a hinge, a first housing connected to the hinge, a first surface and a second surface oriented in a direction opposite to the first surface, a second housing connected to the hinge. The second housing may include a sensor, a third surface and a fourth surface oriented in a direction opposite to the third surface, the first surface facing the third surface in a folded state, and the first surface and the third surface being oriented in a same direction in an unfolded state, a first display provided over the first surface and the third surface.

### CROSS-REFERENCE TO RELATED APPLICATIONS

This application is a bypass continuation application of International Application No. PCT/KR2022/008652, filed on Jun. 17, 2022, which is based on and claims priority to Korean Patent Application No. 10-2021-0093619, filed on Jul. 16, 2021, in the Korean Patent Office, the disclosures of which are incorporated by reference herein in their entireties.

### BACKGROUND

### 1. Field

The disclosure relates to an electronic device and, more particularly, to a foldable electronic device.

### 2. Description of Related Art

Electronic devices have transformed from a uniform rectangular shape into various shapes. For example, the electronic device may be conveniently carried and have a transformable structure which allows use of a large screen display when used. A foldable-type electronic device has been released as an example of such an electronic device.

Recently, an electronic device provides various types of vibration output. The vibration output includes haptic feedback as a representative example. Via the various types of vibration output, various tactual experiences may be provided to a user.

In relation to an electronic device having a transformable structure like a foldable-type electronic device, interest in a control method corresponding to a new structure of the electronic device has increased.

In relation to output for various notifications of an electronic device, a user's requirements may vary for each specific electronic device. For example, the user may desire to detect an optimal vibration corresponding to a structure of the electronic device. For example, when an electronic device has a transformable structure like a foldable-type electronic device, an optimal notification output may be required to correspond to various shapes that the electronic device can have.

In another example, when an event for outputting a vibration is generated during execution of multiple applications, a voice or vibration output of an appropriate priority and an appropriate pattern may be required for each of the applications.

### SUMMARY

According to an aspect of the disclosure, there is provided an electronic device including: a housing structure including: a hinge; a first housing connected to the hinge; a first surface and a second surface oriented in a direction opposite to the first surface; a second housing connected to the hinge, the second housing including a third surface and a fourth surface oriented in a direction opposite to the third surface, the first surface facing the third surface in a folded state, and the first surface and the third surface being oriented in a same direction in an unfolded state; a first display provided over the first surface and the third surface; a sensor; and a processor operatively connected to the sensor, wherein the processor is configured to: detect an unfolding operation or a folding operation of the first housing and the second housing through the sensor; based on the unfolding operation or the folding operation being detected, acquire folding information of the unfolding operation or the folding operation, based on a folding angle formed by the first housing and the second housing; and provide a multimedia notification based on the folding information.

The folding information may include at least one of a size of the folding angle, an angle interval in which the folding angle is included, or a folding angular speed corresponding to an angular speed of the folding angle.

The multimedia notification may include a sound notification, and wherein the processor is further configured to provide, through the sound notification, a sound including a note corresponding to an angle interval in which the folding angle is included.

The processor is further configured to provide, through the sound notification, the corresponding note at a tempo corresponding to an angular speed at which the folding angle changes.

The processor is further configured to identify an output order of a note included in the sound notification, based on a direction in which the folding angle changes.

The multimedia notification may include an image provided through the first display, and wherein the processor is further configured to provide the image to at least a partial area of the first display including an area corresponding to a size of the folding angle.

The image may include a video image, and wherein the processor is further configured to provide the video image at a speed corresponding to an angular speed of the folding angle.

The multimedia notification may include a haptic notification including a vibration output, and wherein the processor is further configured to change at least one of a strength, a speed, or a duration of the vibration output, based on the folding information.

The processor is further configured to: identify whether a notification of an application or a function is generated; based on the notification being generated, identify the folding information; identify notification classification information of the generated notification; and provide the multimedia notification based on the folding information and the notification classification information.

The notification classification information may include at least one of a type, priority information, or contact priority information of the application or the function.

The multimedia notification may include at least one of a haptic notification, a sound notification, or an image notification pre-stored to correspond to the application or the function, and wherein the processor is further configured to change the multimedia notification, based on at least one of the folding information and the notification classification information.

According to an aspect of the disclosure, there is provided a method of providing a multimedia notification by an electronic device including a first housing and a second housing connected to be mutually folded or unfolded, including: detecting an unfolding operation or a folding operation of the first housing and the second housing; based on the unfolding operation or the folding operation being detected, acquiring folding information of the unfolding operation or the folding operation, based on a folding angle formed by the first housing and the second housing; and providing a multimedia notification based on the folding information.

The folding information may include at least one of a size of the folding angle, an angle interval in which the folding angle is included, or a folding angular speed corresponding to an angular speed of the folding angle.

The providing of the multimedia notification may include at least one of: providing, through a sound notification, a sound including a note corresponding to an angle interval in which the folding angle is included; providing an image to an area of the first display, the area including an area corresponding to a size of the folding angle; or providing a haptic notification including a vibration output.

The method may include identifying whether a notification of an application or a function is generated; based on the notification being generated, identifying the folding information; identifying notification classification information of the generated notification; and providing the multimedia notification based on the folding information and the notification classification information.

According to one or more embodiments, various types of notifications can be identified only through an operation of unfolding or folding an electronic device, whereby the usability can be increased.

According to one or more embodiments, a notification is output based on a user physically transforming of the shape of an electronic device, whereby usability of the electronic device upon a user interaction can be increased.

### BRIEF DESCRIPTION OF THE DRAWINGS

With regard to description of drawings, identical or similar reference numerals may be used for identical or similar elements.

FIG. 1 is a block diagram illustrating an electronic device in a network environment according to one or more embodiments;

FIG. 2 illustrates an unfolded state of an electronic device according to various embodiments of the disclosure;

FIG. 3 illustrates a folded state (e.g., a second state) of an electronic device according to one or more embodiments of the disclosure;

FIG. 4 is an exemplary diagram illustrating outputting a notification based on folding information by an electronic device according to one or more embodiments;

FIG. 5 is a block diagram illustrating an electronic device according to one or more embodiments;

FIG. 6 is a flow chart illustrating an operation in which an electronic device outputs a notification based on folding information according to one or more embodiments;

FIG. 7 is an exemplary diagram illustrating folding information according to one or more embodiments;

FIG. 8 illustrates a sound notification based on folding information according to one or more embodiments;

FIG. 9 illustrates a haptic notification based on folding information according to one or more embodiments;

FIG. 10 illustrates an image notification based on folding information according to one or more embodiments;

FIG. 11 is an exemplary diagram illustrating outputting a notification based on notification classification information by an electronic device according to one or more embodiments;

FIG. 12 is a flow chart of an operation in which an electronic device outputs a notification based on notification classification information according to one or more embodiments;

FIG. 13 illustrates contact priority information of notification classification information according to one or more embodiments;

FIG. 14 illustrates application priority information of notification classification information according to one or more embodiments;

FIG. 15 is an exemplary diagram illustrating outputting a notification based on folding information and notification classification information according to one or more embodiments; and

FIG. 16 illustrates an interface for configuring a multimedia notification based on folding information and notification classification information according to one or more embodiments.

### DETAILED DESCRIPTION

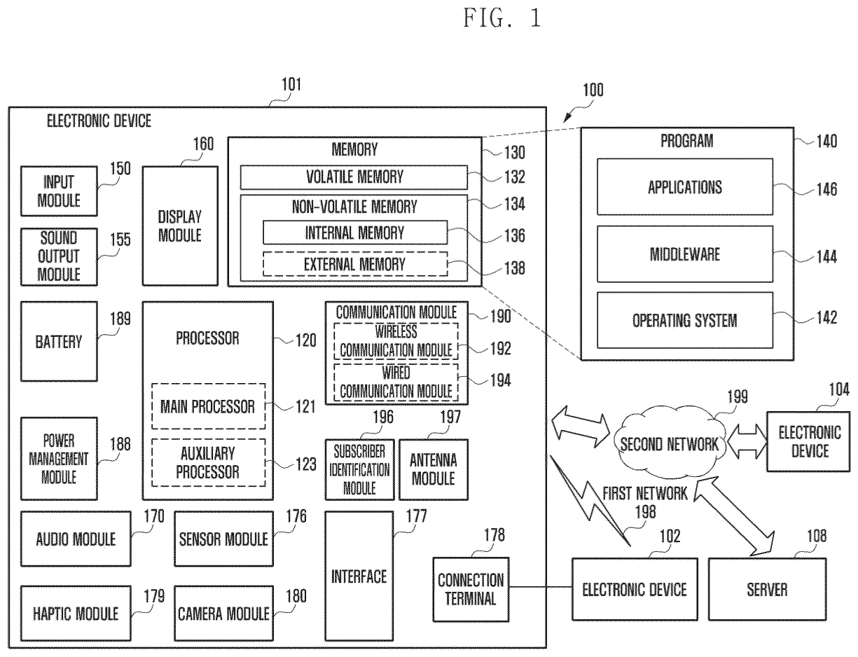

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thererto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

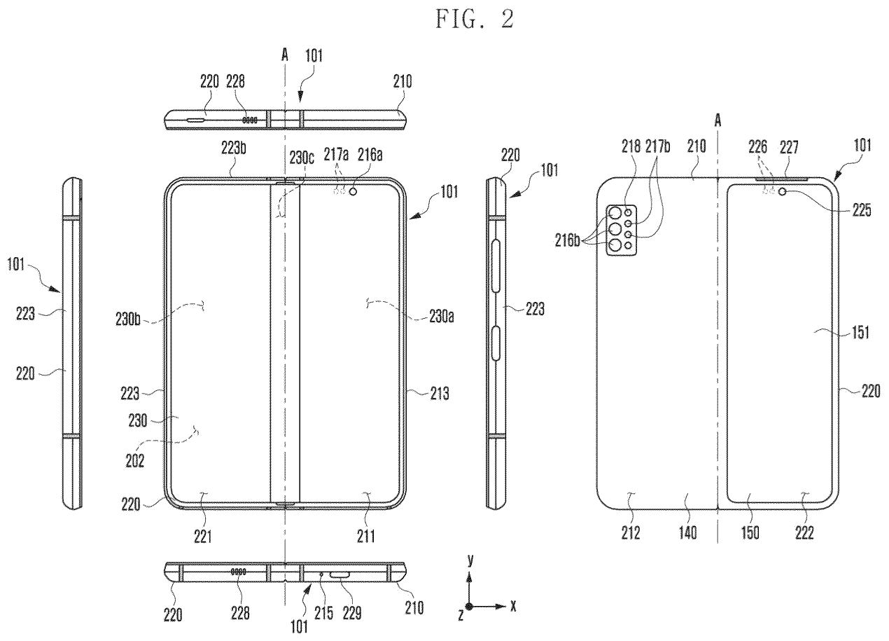

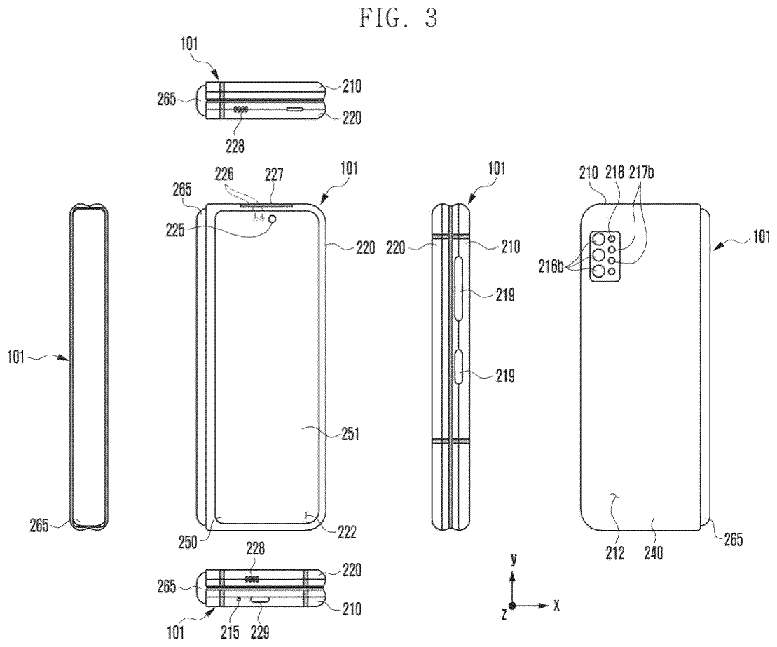

FIG. 2 illustrates an unfolded state (e.g., a first state) of an electronic device 101 according to one or more embodiments of the disclosure. FIG. 3 illustrates a folded state (e.g., a second state) of the electronic device 101 of FIG. 2 according to one or more embodiments of the disclosure.

Referring to FIGS. 2 and 3, the electronic device 101 may include a pair of housings (210 and 220) (e.g., a foldable housing) rotatably coupled with reference to a folding axis A through a hinge device so that the housings can be folded with respect to each other, a first display 230 (e.g., a flexible display, a foldable display, or a main display) disposed through the pair of housings 210 and 220, and a second display 251 (e.g., a sub display). According to an embodiment, the hinge device may be disposed to be hidden from the outside by a first housing 210 and a second housing 220 in a folded state, and may be disposed to be hidden from the outside by a hinge cover 265 for protecting the hinge device and covering a foldable part, in an unfolded state. In the disclosure, a surface on which the first display 230 is disposed may be defined as a front surface of the electronic device 101, and a surface opposite to the front surface may be defined as a rear surface of the electronic device 101. In addition, a surface surrounding a space between the front surface and the rear surface may be defined as a side surface of the electronic device 101.

According to one or more embodiments, the pair of housings 210 and 220 may include the first housing 210 and the second housing 220 arranged to be folded with respect to each other through the hinge device. According to an embodiment, the pair of housings 210 and 220 is not limited to the type or the coupling illustrated in FIGS. 2 and 3, and may be implemented by another shape or a combination and/or coupling of components. According to an embodiment, the first housing 201 and the second housing 220 may be arranged at opposite ends with reference to the folding axis A, and may have substantially symmetrical shapes with respect to the folding axis A. In some embodiments, the first housing 210 and the second housing 220 may be asymmetrically folded with reference to the folding axis A. According to an embodiment, the angle or the distance formed by the first housing 210 and the second housing 220 may vary according to whether the electronic device 101 is in an unfolded stage (e.g., a first state), a folded state (e.g., a second state), or an intermediate state (e.g., a third state).

According to one or more embodiments, the first housing 210 may include, in the unfolded state of the electronic device 101, a first surface 211 connected to the hinge device and disposed to be oriented toward a front surface of the electronic device 101, a second surface 212 oriented in the direction opposite to the first surface 211, and a first side member 213 surrounding at least a part of a first space between the first surface 211 and the second surface 212. According to an embodiment, the second housing 220 may include, in the unfolded state of the electronic device 101, a third surface 221 connected to the hinge device and disposed to be oriented toward the front surface of the electronic device 101, a fourth surface 222 oriented in the direction opposite to the third surface 221, and a second side member 223 surrounding at least a part of a second space between the third surface 221 and the fourth surface 222. According to an embodiment, the first surface 211 may be oriented in the same direction as the third surface 221 in the unfolded state, and may face with the third surface 221 in the folded state. According to an embodiment, the electronic device 101 may include a recess 202 formed to receive the first display 230 through structural coupling of the first housing 210 and the second housing 220. According to an embodiment, the recess 202 may have substantially the same size as the first display 230.

According to one or more embodiments, the hinge cover 265 may be disposed between the first housing 210 and the second housing 220, and may be disposed to cover the hinge device. According to an embodiment, the hinge cover 265 may be covered by a part of the first housing 210 and the second housing 220 or exposed to the outside according to the unfolded state, the folded state, the intermediate state of the electronic device 101. For example, when the electronic device 101 is in the unfolded state, the hinge cover 265 may be covered by the first housing 210 and the second housing 220 and may not be exposed. According to an embodiment, when the electronic device 101 is in the folded state, the hinge cover 265 may be exposed to the outside between the first housing 210 and the second housing 220. According to an embodiment, in a case of the intermediate state in which the first housing 210 and the second housing 220 have a predetermined angle therebetween (are folded with a certain angle), the hinge cover 265 may be at least partially exposed to the outside between the first housing 210 and the second housing 220. For example, the exposed area of the hinge cover 265 may be smaller than that in a case of a fully folded state. According to an embodiment, the hinge cover 265 may include a curved surface.

According to one or more embodiments, when the electronic device 101 is in the unfolded state (e.g., the state in FIG. 2), the first housing 210 and the second housing 220 may have an angle of 180 degrees therebetween, and a first area 230a, a folding area 230c, and a second area 230b of the first display 230 may form the same plane and may be arranged to be oriented in the same direction. According to an embodiment, when the unfolded state of the electronic device 101, the first housing 210 may rotate at an angle of 360 degrees with respect to the second housing 220 so that the second surface 212 and the fourth surface 222 may be reversely folded to face each other (an out-folding scheme).

According to one or more embodiments, when the electronic device 101 is in the folded state (e.g., the state in FIG. 3), the first surface 211 of the first housing 210 and the third surface 221 of the second housing 220 may be arranged to face each other. In such a case, the first area 230 and the second area 230b of the first display 230 may form a narrow angle (e.g., a range of 0 degree to 10 degrees) therebetween through the folding area 230c, and may be arranged to face each other. According to an embodiment, at least a part of the folding area 230c may be formed in a curved surface having a predetermined curvature. According to an embodiment, when the electronic device 101 is in the intermediate state, the first housing 210 and the second housing 220 may be arranged at a predetermined angle (certain angle) to each other. In such a case, the first area 230a and the second area 230b of the first display 230 may form an angle large than that in the folded state and smaller than that in the unfolded state, and a curvature of the folding area 230c may be larger than that in the folded state. In some embodiments, the first housing 210 and the second housing 220 may form an angle that may stop at a designated folding angle between the folded state and the unfolded state through the hinge device (free stop function). In some embodiments, the first housing 210 and the second housing 220 may operate while being pressurized in an unfolding direction or a folding direction with reference to a designated inflection angle through the hinge device.

According to one or more one or more embodiments, the electronic device 101 may include at least one of at least one display 230 and 251 disposed on the first housing 210 and/or the second housing 220, an input device 215, sound output devices 227 and 228, sensor modules 271a, 271b, and 226, camera modules 216a, 216b, and 225, a key input device 219, an indicator, or a connector port 229. In some embodiments, the electronic device 101 may omit at least one among elements, or may additionally include at least one other element.

According to one or more embodiments, the at least one display 230 and 251 may include the first display 230 (e.g., a flexible display) disposed to be supported by the third surface 221 of the second housing 220 from the first surface 211 of the first housing 210 from the hinge device, and the second display 251 disposed to be visible to the outside through the fourth surface 222 in an inner space of the second housing 220. According to an embodiment, the first display 230 may be mostly used in the unfolded state of the electronic device 101, and the second display 251 may be mainly used in the folded state of the electronic device 101. According to an embodiment, in a case of the intermediate state, the electronic device 101 may use the first display 230 or the second display 251, based on the folding angle of the first housing 210 and the second housing 220.

According to one or more embodiments, the first display 230 may be disposed in a space formed by the pair of housings 210 and 220. For example, the first display 230 may be safely mounted in the recess 202 formed by the pair of housings 210 and 220, and may be disposed to occupy substantially most of the front surface of the electronic device 101. According to an embodiment, the first display 230 may include a flexible display, the at least partial area of which may be transformed into a flat surface or a curved surface. According to an embodiment, the first display 230 may include the first area 230a facing the first housing 210, the second area 230b facing the second housing 220, and the folding area 230c for connecting the first area 230a and the second area 230b and facing the hinge device.

According to an embodiment, the first area 230a of the first display 230 may substantially form the first surface 211 of the first housing 210. According to an embodiment, the second area 230b of the first display 230 may substantially form the third surface 221 of the second housing 220.

According to an embodiment, area division of the first display 230 is merely provided as exemplary physical division by the pair of housings 210 and 220 and the hinge device, and the first display 230 may be displayed as a substantially seamless single full screen through the pair of housings 210 and 220 and the hinge device. According to an embodiment, the first area 230a and the second area 230b may have an overall symmetrical shape or a partially asymmetrical shape, based on the folding area 230c.

According to one or more embodiments, the electronic device 101 may include a first rear cover 240 disposed on the second surface 212 of the first housing 210, and a second rear cover 250 disposed on the fourth surface 222 of the second housing 220. In some embodiments, at least a part of the first rear cover 240 may be integrally formed with the first side member 213. In some embodiments, at least a part of the second rear cover 250 may be integrally formed with the second side member 223. According to an embodiment, at least one of the first rear cover 240 and the second rear cover 250 may be formed through a substantially transparent plate (e.g., a polymer plate or a glass plate including various coating layers) or an opaque plate. According to an embodiment, the first rear cover 240 may be formed by an opaque plate such as coated or tinted glass, ceramic, polymer, metal (e.g., aluminum, stainless steel (STS), or magnesium), or a combination of at least two of the above materials, for example. According to an embodiment, the second rear cover 250 may be formed through a substantially transparent plate such as glass or polymer, for example. Accordingly, the second display 251 may be disposed to be visible from the outside through the second rear cover 250 in an inner space of the second housing 220.

According to one or more embodiments, the input device 215 may include a microphone 215. In some embodiments, the input device 215 may include multiple microphones 215 arranged to detect the direction of a sound. According to an embodiment, the sound output devices 227 and 228 may include speakers 227 and 228. According to an embodiment, the speakers 227 and 228 may include a call receiver 227 disposed through the fourth surface 222 of the second housing 220, and an external speaker 228 disposed through a side member of the second housing 220. In some embodiments, the microphone 215, the speakers 227 and 228, and a connector 229 may be arranged in spaces of the first housing 210 and/or the second housing 220, and may be exposed to an external environment through at least one hole formed in the first housing 210 and/or the second housing 220. In some embodiments, holes formed in the first housing 210 and/or the second housing 220 may be commonly used for the microphone 215 and the speakers 227 and 228. In some embodiments, the sound output devices 227 and 228 may include a speaker (e.g., piezo speaker) operating while excluding a hole formed in the first housing 210 and/or the second housing 220.

According to one or more embodiments, the camera modules 216a, 216b, and 225 may include a first camera device 216a disposed on the first surface 210 of the first housing 210, a second camera device 216b disposed on the second surface 212 of the first housing 210, and/or a third camera device 225 disposed on the fourth surface 222 of the second housing 220. According to an embodiment, the electronic device 101 may include a flash 218 disposed near the second camera device 216b. According to an embodiment, the flash 218 may include, for example, a light emitting diode or a xenon lamp. In an embodiment, the camera devices 216a, 216b, and 225 may include one or multiple lenses, an image sensor, and/or an image signal processor. In some embodiments, at least one camera device among the camera devices 216a, 216b, and 225 may include two or more lenses (e.g., wide-angle and telephoto lenses) and image sensors, and may disposed together on one surface of the first housing 210 and/or the second housing 220.

According to one or more embodiments, the sensor modules 217a, 217b, and 226 may acquire an electrical signal or a data value corresponding to an internal operating state of the electronic device 101 or an external environment state. According to an embodiment, the sensor modules 217a, 217b, and 226 may include a first sensor module 217a disposed on the first surface 211 of the first housing 210, a second sensor module 217b disposed on the second surface 212 of the first housing 210, and/or a third sensor module 226 disposed on the fourth surface 222 of the second housing 220. In some embodiments, the sensor modules 217a, 217b, and 226 may include at least one of a gesture sensor, a grip sensor, a color sensor, an infrared (IR) sensor, an illuminance sensor, an ultrasonic sensor, an iris recognition sensor, or a distance detection sensor (e.g., time of flight (TOF) sensor or light detection and ranging (LiDAR)).

According to one or more embodiments, the electronic device 101 may further include a sensor module, for example, at least one of an atmospheric pressure sensor, an angle sensor, a gyro sensor, a magnetic sensor, a biometric sensor, a temperature sensor, a humidity sensor, or a fingerprint recognition sensor. In some embodiments, the fingerprint recognition sensor may be disposed through at least one of the first side member 213 of the first housing 210 and/or the second side member 223 of the second housing 220.

According to one or more embodiments, the key input device 219 may be disposed to be exposed to the outside through the first side member 213 of the first housing 210. In some embodiments, the key input device 219 may be disposed to be exposed to the outside through the second side member 223 of the second housing 220. In some embodiments, the electronic device 200 may not include some or all of the key input devices 219, and the key input devices 219, which are not included, may be implemented into other forms such as soft keys on at least one display 230 and 251. As another embodiment, the key input device 219 may be implemented using a pressure sensor included in at least one display 230 and 251.

According to one or more embodiments, a connector port 229 may receive a connector (e.g., a USB connector or an interface connector port module (IF module)) for transmitting or receiving power and/or data to or from an external electronic device. In some embodiments, the connector port 229 may further include a separate connector port (e.g., ear jack hole) for performing together a function for transmitting or receiving an audio signal to or from an external electronic device or for performing a function of transmitting or receiving an audio signal.

According to one or more embodiments, at least one camera module 216a and 225 of the camera modules 216a, 216b, and 225, at least one sensor module 217a and 226 of the sensor modules 217a, 217b, and 226, and/or the indicator may be arranged to be visually exposed through at least one display 230 and 251. For example, the at least one camera module 216a and 225, the at least one sensor module 217a and 226, and/or the indicator may be arranged under a display area of the displays 230 and 251 in an interior space of the at least one housing 210 and 220, and may be disposed to contact an external environment through an opening perforated to a cover member (e.g., a window layer of the first display 230 and/or the second rear cover 250). In another embodiment, some camera devices or sensor modules may be arranged to perform functions thereof without being visually exposed through the display. For example, a perforated opening may not be necessary for an area facing the camera device and/or the sensor modules of the display (e.g., a display panel).

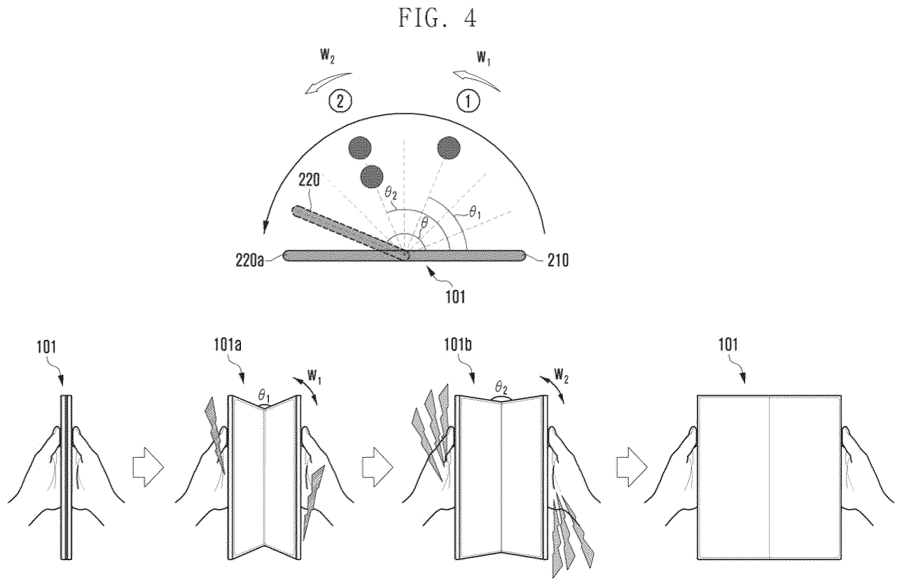

FIG. 4 is an exemplary diagram illustrating outputting a notification based on folding information by an electronic device according to one or more embodiments.

Referring to FIG. 4, an electronic device 101 may include a first housing 210 and a second housing 220 connected to be mutually folded or unfolded. According to one or more embodiments, the electronic device 101 may form a folding angle θ while being folded or unfolded. The folding angle θ may be understood as an angle formed between the first housing 210 and the second housing 220. According to one or more embodiments, the electronic device 101 may identify the folding angle θ. According to an embodiment, the electronic device 101 may measure the folding angle θ during a folding or unfolding operation of the electronic device 101 through a sensor module (e.g., the sensor module 176 of FIG. 1). The electronic device 101 may measure the folding angle θ according to a predetermined period, or may consecutively measure the folding angle θ. According to one or more embodiments, the electronic device 101 may identify a folding angular speed w1 or w2. According to an embodiment, the electronic device 101 may measure an angular speed during the folding or unfolding operation of the electronic device 101 by using the sensor module 176. Alternatively, the electronic device 101 may calculate the angular speed in real time, based on the folding angle θ.

According to one or more embodiments, the electronic device 101 may detect the folding or unfolding operation. According to an embodiment, the electronic device 101 may detect a change in the folding angle θ or the folding angular speed w1 or w2, and may identify that the folding or unfolding operation is initiated, based on the change in the folding angle θ or the folding angular speed w1 or w2.

According to an embodiment, the electronic device 101 may acquire folding information. The folding information may be understood as information indicating a folded or unfolded state of the electronic device 101. According to an embodiment, the folding information may include at least a part of information on the folding angle θ, the folding angular speed w1 or w2, and a folding angle interval. The folding angle interval may be understood as information on an angle interval to which a current folding angle θ belongs. According to an embodiment, the electronic device 101 may identify, in real time, at least one of the folding angle θ, the folding angular speed w1 or w2, and the folding angle interval, and may acquire folding information relating to at least one of the folding angle θ, the folding angular speed w1 or w2, and the folding interval information.

According to one or more embodiments, the electronic device 101 may output a multimedia notification, based on the folding information. The multimedia notification may mean various types of notifications outputable by the electronic device 101. The various types of notifications may include, for example, a sound notification (or a voice notification) through an audio module (e.g., the audio module 170 of FIG. 1), a haptic notification using a haptic module (e.g., the haptic module 179 of FIG. 1), and an image notification using the display module 160. According to an embodiment, the multimedia notification may be a notification for transferring the folding information of the electronic device 101 to a user, or may include a notification related to the folding information and/or an application or function of the electronic device 101.

Referring to FIG. 4, the electronic device 101 may output the multimedia notification, based on the folding information. For example, the electronic device 101 may have a folding angle of θ1 and a folding angular speed of w1 in state \textcircled{1} during the folding or unfolding operation. According to an embodiment, an electronic device 101a in state \textcircled{1} may output a multimedia notification, based on a first folding angle θ1, a first folding angular speed w, and an angle interval to which the first folding angle θ1 belongs. In another example, the electronic device 101 may have a folding angle of θ2 and a folding angular speed of w2 in state \textcircled{2} during the folding or unfolding operation. According to an embodiment, an electronic device 101b in state \textcircled{2} may output a multimedia notification, based on a second folding angle θ2, a second folding angular speed w2, and an angle interval to which the second folding angle θ2 belongs. According to an embodiment, the electronic device 101 may configure a multimedia output in state \textcircled{1} and a multimedia output in state \textcircled{2} to be different from each other. As the folding or the unfolding operation proceeds, that is, as the state is changed from state \textcircled{1} to state \textcircled{2} or changed from state \textcircled{2} to state \textcircled{1}, the electronic device 101 may consecutively output the multimedia notification. According to an embodiment, the electronic device 101 may pre-store information on the multimedia notification corresponding to the folding information. For example, the electronic device 101 may pre-store information on the sound notification corresponding to the folding information, i.e., information on at least one of a note, a tempo, and a note order corresponding to the folding information. In another example, the electronic device 101 may pre-store information on a haptic notification corresponding to the folding information, i.e., information on at least one of a vibration strength, a speed, and a duration corresponding to the folding information. In another example, the electronic device 101 may pre-store information on an image notification corresponding to the folding information, i.e., information on at least a part of an image area and an image reproduction speed corresponding to the folding information.

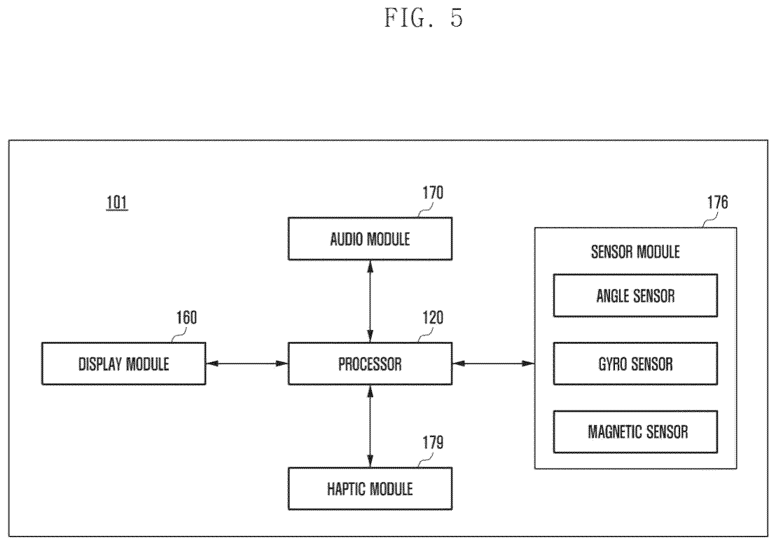

FIG. 5 is a block diagram illustrating an electronic device according to various embodiments.

Referring to FIG. 5, an electronic device 101 (e.g., the electronic device 101 of FIG. 1) may include a processor 120, a display module 160, an audio module 170, a sensor module 176, and/or a haptic module 179. The electronic device 101 may include at least a part of the configuration and/or function of the electronic device 101 of FIGS. 1 and 2 and/or FIG. 3.

According to various embodiments, the display module 160 may visually provide information to the outside (e.g., a user) of the electronic device 101. According to an embodiment, the display module 160 may include a touch sensor adapted to detect a touch, or a pressure sensor adapted to measure the intensity of force incurred by the touch.

According to various embodiments, the audio module 170 may output a voice signal to the outside of the electronic device 101. According to an embodiment, the audio module 170 may include a sound output module (e.g., the sound output module 155 of FIG. 1) for outputting a sound, such as a speaker. According to an embodiment, the audio module 170 may covert an electrical signal into a voice to output the same to the outside. For example, the audio module 170 may output a sound notification to the outside of the electronic device 101.

According to various embodiments, the sensor module 176 may detect an operational state (e.g., power or temperature) of the electronic device 101 or an environmental state (e.g., a state of a user) external to the electronic device 101, and acquire an electrical signal or data value corresponding to the detected state. According to an embodiment, the sensor module 176 may include, for example, an angle sensor, a gyro sensor, a magnetic sensor, an acceleration sensor, a proximity sensor, or an illuminance sensor. According to an embodiment, the sensor module 176 may detect the folding angle θ or the folding angular speed w1 or w2 of the electronic device 101.

According to various embodiments, the haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may output, for example, a vibration notification, and the vibration notification may include various intensities.

According to various embodiments, the processor 120 may be electrically connected to various components (e.g., the display module 160, the audio module 170, the sensor module 176, and/or the haptic module 179) of the electronic device 101 to control the same, and may perform various data processing or computation. According to an embodiment, the processor 120 may include an application processor (AP) (e.g., the main processor 121 of FIG. 1) and/or an image signal processor (ISP) (e.g., the auxiliary processor 123 of FIG. 1). The type and/or the amount of the operation, computation, and data processing which can be performed by the processor 120 may not be limited, but the disclosure only describes the configuration and function of the processor 120 related to the notification output control method and the operation of performing the method based on the folding information of the electronic device 101 according to various embodiments.

According to various embodiments, the processor 120 may identify a folding angle (e.g., the folding angle θ of FIG. 4) of the electronic device 101. The folding angle θ may be understood as an angle formed between a first housing (e.g., the first housing 210 of FIG. 2) and a second housing (e.g., the second housing 220 of FIG. 2). According to an embodiment, the processor 120 may measure the folding angle θ during a folding or unfolding operation of the electronic device 101 through a sensor module (e.g., the sensor module 176 of FIG. 5). The processor 120 may measure the folding angle θ according to a predetermined period, or may consecutively measure the folding angle θ. According to various embodiments, the processor 120 may identify a folding angular speed (e.g., the first angular speed w1 or the second angular speed w2 of FIG. 4). According to an embodiment, the processor 120 may measure an angular speed during the folding or unfolding operation of the electronic device 101 by using the sensor module 176. Alternatively, the processor 120 may calculate the angular speed in real time, based on the folding angle θ.

According to various embodiments, the processor 120 may detect the folding or unfolding operation. According to an embodiment, the processor 120 may detect a change in the folding angle θ or the folding angular speed w1 or w2, and may identify that the folding or unfolding operation is initiated, based on the change in the folding angle θ or the folding angular speed w1 or w2.

According to various embodiments, the processor 120 may acquire folding information. The folding information may be understood as information indicating a folded or unfolded state of the electronic device 101. According to an embodiment, the folding information may include at least a part of information on the folding angle θ, the folding angular speed w1 or w2, and a folding angle interval. The folding angle interval may be understood as information on an angle interval to which a current folding angle θ belongs. According to an embodiment, the processor 120 may identify, in real time, at least one of the folding angle θ, the folding angular speed w1 or w2, and the folding angle interval, and may acquire folding information relating to at least one of the folding angle θ, the folding angular speed w1 or w2, and the folding interval information.

According to various embodiments, the processor 120 may output a multimedia notification, based on the folding information. The multimedia notification may mean various types of notifications outputtable by the electronic device 101. The various types of notifications may include, for example, at least one of a sound notification through the audio module 170, a haptic notification using the haptic module 179, and an image notification using the display module 160. According to an embodiment, the multimedia notification may be a notification for transferring the folding information of the electronic device 101 to a user, or may include a notification related to the folding information and/or an application or function of the electronic device 101. According to an embodiment, information on the multimedia notification corresponding to the folding information may be pre-stored in a memory (e.g., the memory 130 of FIG. 1) of the electronic device 101. According to an embodiment, the processor 120 may identify information on the multimedia notification corresponding to the pre-stored folding information, and output the multimedia notification. For example, the processor 120 may identify information on the sound notification corresponding to the folding information, i.e., pre-stored information on at least one of a note, a tempo, and a note order corresponding to the folding information, and output the notification. In another example, the processor 120 may identify information on a haptic notification corresponding to the folding information, i.e., pre-stored information on at least one of a vibration strength, a speed, and a duration corresponding to the folding information. In another example, the processor 120 may identify information on an image notification corresponding to the folding information, i.e., pre-stored information on at least a part of an image area and an image reproduction speed corresponding to the folding information.

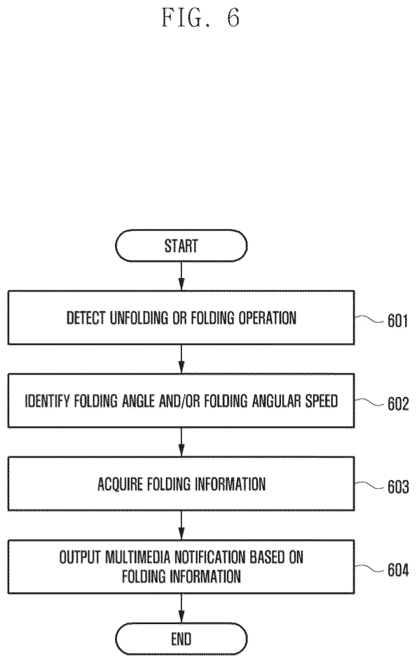

FIG. 6 is a flow chart of an operation of outputting a notification based on folding information by an electronic device according to various embodiments.

Referring to FIG. 6, an operation of outputting a notification based on folding information by an electronic device (e.g., the electronic device 101 of FIG. 1 or FIG. 5) may be understood as a series of operations performed by a processor (e.g., the processor 120 of FIG. 1 or FIG. 5) of the electronic device. All or some of the respective operations of FIG. 6 may be changed to and/or substituted with other operations, and the order thereof may be changed.

Referring to operation 601, the processor 120 may detect a folding or unfolding operation. According to an embodiment, the processor 120 may detect a change in a folding angle or a folding angular speed of the electronic device 101. According to an embodiment, in order to acquire and identify folding information to cause the processor 120 to output a multimedia notification, an operation in which the electronic device 101 is folded or unfolded may need to be detected. The processor 120 may detect the folding angle by using a sensor module (e.g., the sensor module 176 of FIG. 6), and may identify that the folding or unfolding operation is initiated, based on the change in the folding angle or the folding angular speed.

Referring to operation 602, the processor 120 may identify a folding angle (e.g., the folding angle θ of FIG. 4) of the electronic device 101. The folding angle θ may be understood as an angle formed between a first housing (e.g., the first housing 210 of FIG. 2) and a second housing (e.g., the second housing 220 of FIG. 2). According to an embodiment, the processor 120 may measure the folding angle θ during the folding or unfolding operation of the electronic device 101 through a sensor module (e.g., the sensor module 176 of FIG. 5). The processor 120 may measure the folding angle θ according to a predetermined period, or may consecutively measure the folding angle θ. According to various embodiments, the processor 120 may identify a folding angular speed (e.g., the first angular speed w1 or the second angular speed w2 of FIG. 4). According to an embodiment, the processor 120 may measure an angular speed during the folding or unfolding operation of the electronic device 101 by using the sensor module 176. Alternatively, the processor 120 may calculate the angular speed in real time, based on the folding angle θ.

Referring to operation 603, the processor 120 may acquire folding information. The folding information may be understood as information indicating a folded or unfolded state of the electronic device 101. According to an embodiment, the folding information may include at least a part of information on the folding angle θ, the folding angular speed w1 or w2, and a folding angle interval. The folding angle interval may be understood as information on an angle interval to which a current folding angle θ belongs. According to an embodiment, the processor 120 may identify, in real time, at least one of the folding angle θ, the folding angular speed w1 or w2, and the folding angle interval, and may acquire folding information relating to at least one of the folding angle θ, the folding angular speed w1 or w2, and the folding interval information.

Referring to operation 604, the processor 120 may output a multimedia notification, based on the folding information. The multimedia notification may mean various types of notifications outputtable by the electronic device 101. The various types of notifications may include, for example, at least one of a sound notification through an audio module (e.g., the audio module 170 of FIG. 5), a haptic notification using a haptic module (e.g., the haptic module 179 of FIG. 5), and an image notification using a display module (e.g., the display module 160 of FIG. 5). According to an embodiment, the multimedia notification may be a notification for transferring the folding information of the electronic device 101 to a user, or may include a notification related to the folding information and/or an application or function of the electronic device 101. According to an embodiment, information on the multimedia notification corresponding to the folding information may be pre-stored in a memory (e.g., the memory 130 of FIG. 1) of the electronic device 101. According to an embodiment, the processor 120 may identify information on the multimedia notification corresponding to the pre-stored folding information, and output the multimedia notification. For example, the processor 120 may identify information on the sound notification corresponding to the folding information, i.e., pre-stored information on at least one of a note, a tempo, and a note order corresponding to the folding information, and output the notification. In another example, the processor 120 may identify information on a haptic notification corresponding to the folding information, i.e., pre-stored information on at least one of a vibration strength, a speed, and a duration corresponding to the folding information, and may output the notification. In another example, the processor 120 may identify information on an image notification corresponding to the folding information, i.e., pre-stored information on at least a part of an image area and an image reproduction speed corresponding to the folding information, and may output the notification.

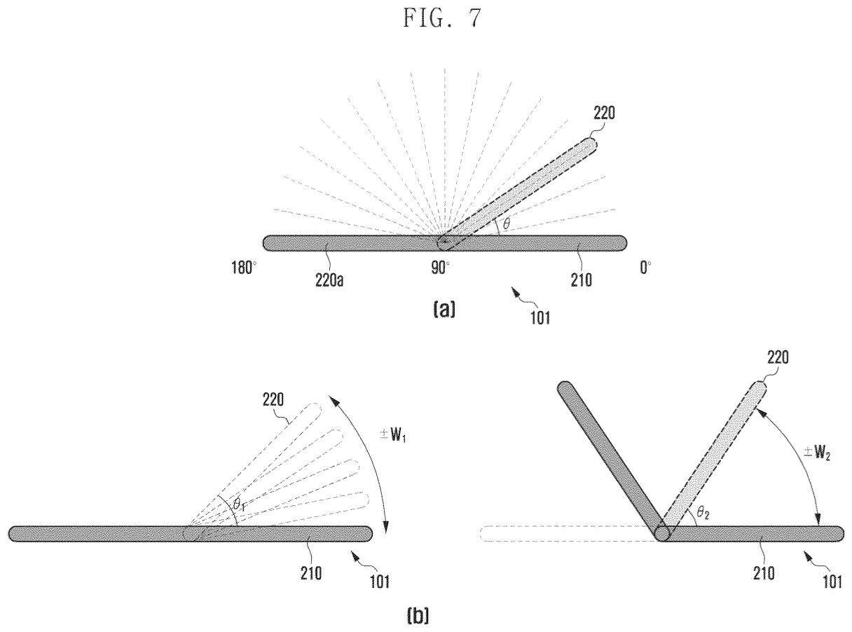

FIG. 7 is an exemplary diagram illustrating folding information according to various embodiments.

Part [a] of FIG. 7 illustrates a folding angle θ and a folding angle interval of an electronic device 101 according to various embodiments. Part [b] of FIG. 7 illustrates an angular speed of the electronic device 101 according to various embodiments.

Referring to parts [a] and [b] of FIG. 7, the electronic device 101 may acquire folding information. The folding information may be understood as information indicating a folded or unfolded state of the electronic device 101. The electronic device 101 may include a first housing 210 and a second housing 220 foldably or unfoldably connected to the first housing 210. The electronic device 101 may form a folding angle θ between the first housing 201 and the second housing 220 while being folded or unfolded. According to an embodiment, the folding information may include at least a part of information on the folding angle θ, a folding angular speed w1 or w2, and a folding angle interval. The folding interval may be understood as information on an angle interval to which a current folding angle θ belongs. According to an embodiment, the electronic device 101 may identify, in real time, at least one of the folding angle θ, the folding angular speed w1 or w2, and the folding angle interval, and may acquire folding information relating to at least one of the folding angle θ, the folding angular speed w1 or w2, and the folding interval information.

Referring to part [a] of FIG. 7, the first housing 210 and the second housing 220 of the electronic device 101 may form a folding angle θ of 0 to 180 degrees according to the unfolded or folded state. For example, the second housing 220 may be unfolded to a location 220a at which the second housing is level with the first housing 210 with reference to the location of the first housing 210. In another example, the second housing 220 may rotate and form a folding angle θ of 0 to 360 degrees. According to an embodiment, an interval of the folding angle θ may mean an interval to which a current folding angle θ belongs among the entire interval (e.g., 0 to 180 degrees) in which the folding angle θ of the electronic device 101 can be formed. For example, the folding angle interval may include pre-divided multiple angle intervals among the entire angle interval (e.g., 0 to 180 degrees). For example, when the entire angle interval is divided into a first interval (e.g., 0 degree or more and 60 degrees of less), a second interval (e.g., 60 degrees or more and 120 degrees or less), and a third interval (e.g., 120 degrees or more and 180 degrees or less), an interval to which the current folding angle θ belongs may mean the interval of the folding angle θ.

Referring to part [b] of FIG. 7, the folding angle θ formed while the electronic device 101 is folded or unfolded may be changed. According to an embodiment, the electronic device 101 may form a folding angular speed (e.g., a first angular speed w1 and a second angular speed w2), based on a change amount per hour of the folding angle θ of the electronic device 101. The folding angular speed may be understood as the amount of a change in the folding angle θ per unit time, and may thus include a positive value and a negative value. For example, when the folding angle θ increases, that is, when the electronic device 101 is unfolded, the folding angular speed may have a positive value, and when the folding angle θ decreases, that is, when the electronic device 101 is folded, the folding angular speed may have a negative value. According to a tempo of the folding and the unfolding operation of the electronic device 101, an effect of outputting different multimedia notifications of the electronic device 101 can be achieved. The folding angular speed may be a reference to the tempo of the folding or unfolding operation of the electronic device 101. Referring to part [b] of FIG. 7, when the electronic device 101 is unfolded at the first folding angle θ1 during unit time, the electronic device 101 may have the first angular speed w1. Alternatively, the electronic device 101 may have an instant angular speed in the unfolded direction, i.e., the first angular speed w1. Similarly, referring to part [b] of FIG. 7, when the electronic device 101 is unfolded at the second folding angle θ2 during unit time, the electronic device 101 may have the second angular speed w2. Alternatively, the electronic device 101 may have an instant angular speed in the unfolded direction, i.e., the second angular speed w2.

According to various embodiments, the electronic device 101 may acquire folding information. According to an embodiment, the folding information may include at least a part of information on the folding angle θ, the folding angular speed w1 or w2, and the folding angle interval. According to an embodiment, the electronic device 101 may identify, in real time, at least one of the folding angle θ, the folding angular speed w1 or w2, and the folding angle interval, and may acquire folding information relating to at least one of the folding angle θ, the folding angular speed w1 or w2, and the folding interval information.

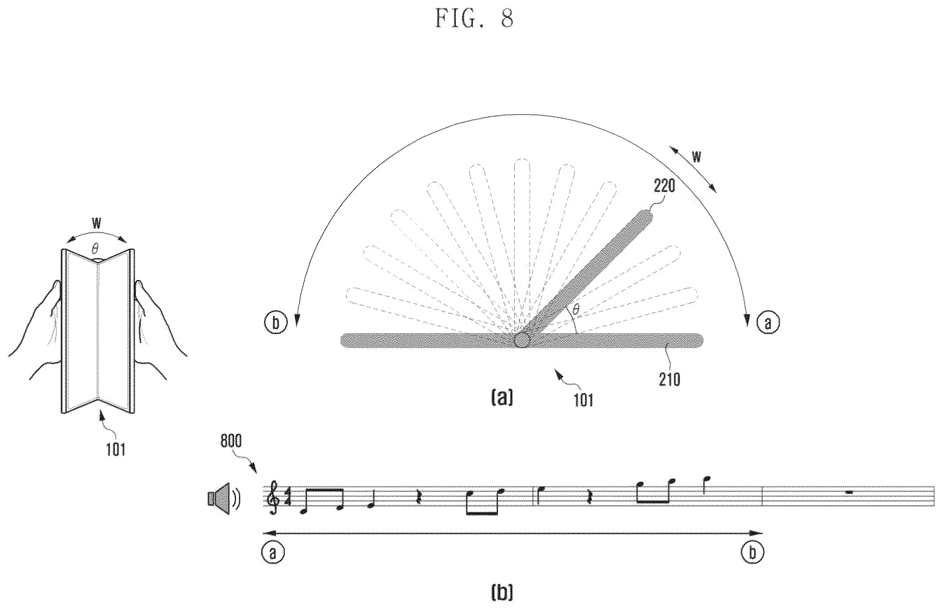

FIG. 8 illustrates a sound notification based on folding information according to various embodiments.

Part [a] of FIG. 8 illustrates folding information. Part [b] of FIG. 8 illustrates an example of sound notification information 800.

Referring to part [a] of FIG. 8, with reference to the first housing 210, the second housing 220 may rotate within a range of location \textcircled{a} and location \textcircled{b}, and a folding or unfolding operation of the electronic device 101 may be performed according to the rotation. According to an embodiment, according to the unfolding or folding, the electronic device 101 may form a folding angle θ and a folding angular speed w. According to an embodiment, the electronic device 101 may identify the folding angle θ, the folding angular speed w, and a folding angle interval to which the folding angle θ belongs, and may acquire folding information.

Referring to part [b] of FIG. 8, the electronic device 101 may output a sound notification (or a voice notification) based on sound notification information 800. According to an embodiment, the sound notification information 800 may include information on at least one note to be output and information on a duration and/or an interval of at least one note. According to an embodiment, the electronic device 101 may output the sound notification based on the folding information. According to an embodiment, the electronic device 101 may change the sound notification information 800 based on the folding information. For example, the electronic device 101 may output a note corresponding to the folding angle θ and/or the folding angle interval among at least one note included in the sound notification information 800. In another example, the electronic device 101 may change an output order, a tempo (e.g., an output interval), and/or durations of one or more notes included in the sound notification information 800, based on the folding angular speed w. For example, when the second housing 220 proceeds in the direction from location \textcircled{b} to location \textcircled{a}, that is, when the electronic device 101 is folded, the output order of the notes included in the sound notification information 800 may be changed to direction of \textcircled{b} or \textcircled{a}, and the sound may be output. In addition, for example, the output of the sound in part [b] of FIG. 8 may be controlled to start from a note at \textcircled{a} and end with a note at \textcircled{b} until the state of the electronic device 101 is changed from the closed state to the unfolded state. In this case, a note corresponding to the folding angle θ and/or the folding angle interval is output, thus notes of the sound may be quickly played when the folding angular speed w is fast, and notes of the sound may be slowly played when the folding angular speed w is slow.

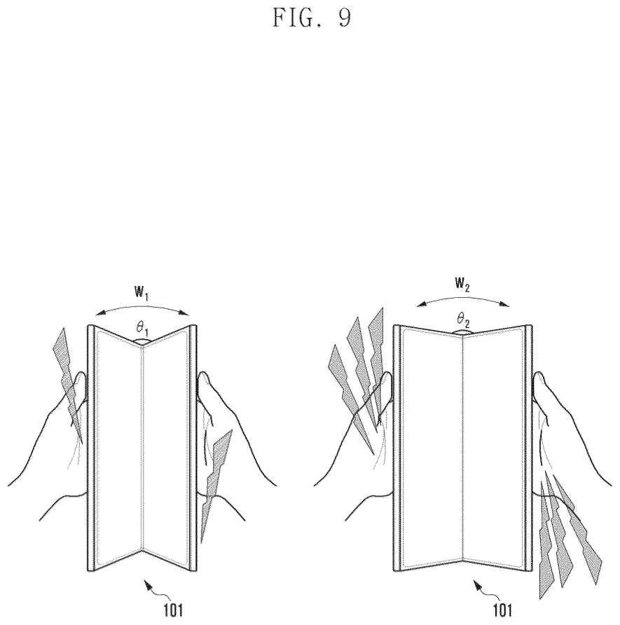

FIG. 9 illustrates a haptic notification based on folding information according to various embodiments.

Referring to FIG. 9, the electronic device 101 may be folded or unfolded. According to an embodiment, the electronic device 101 may form a folding angle θ and a folding angular speed w. According to an embodiment, the electronic device 101 may identify the folding angle θ, the folding angular speed w, and/or a folding angle interval to which the folding angle θ belongs, and acquire folding information.

Referring to FIG. 9, the electronic device 101 may output a haptic notification based on folding information. According to an embodiment, the haptic notification which can be output by the electronic device 101 may include a vibration notification. The electronic device 101 may output the haptic notification including various intensities, speeds, and/or durations. According to an embodiment, the electronic device 101 may identify information on the haptic notification corresponding to the folding information, i.e., pre-stored information relating to at least one of a vibration strength, a speed, and a duration corresponding to the folding information, and may output the notification.

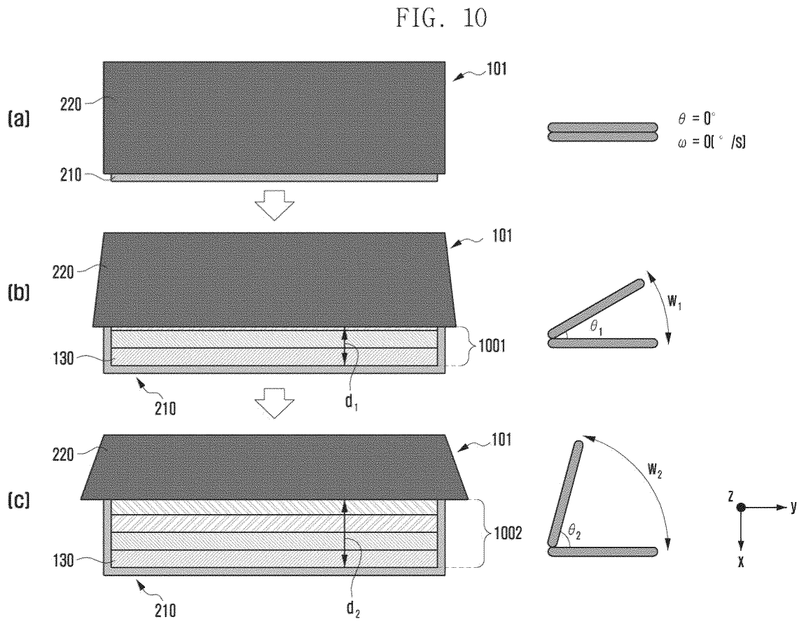

FIG. 10 illustrates an image notification based on folding information according to various embodiments.

Referring to FIG. 10, with reference to a first housing 210, a second housing 220 may rotate while being connected to the first housing 210, and a folding or unfolding operation of the electronic device 101 may be performed according to the rotation. According to an embodiment, the electronic device 101 may form a folding angle θ and a folding angular speed w according to unfolding or folding. According to an embodiment, the electronic device 101 may identify the folding angle θ, the folding angular speed w, and/or a folding angle interval to which the folding angle θ belongs, and may acquire folding information.

According to various embodiments, the electronic device 101 may output an image notification based on folding information. According to an embodiment, the electronic device 101 may pre-store information on an image to be output as an image notification and/or information on an output area of the image notification. According to an embodiment, the image notification may include a video image. The electronic device 101 may pre-store information on a reproduction area and/or a reproduction speed of the video image. The electronic device 101 may determine an image reproduction area, based on the folding information. For example, areas on the display 130 which can be visually identified by a user may vary according to a folding angle formed by the electronic device 101. For example, as shown in part [b] of FIG. 10, when the electronic device 101 forms a folding angle of θ1, the electronic device 101 may output an image notification (e.g., a first image notification 1001) only in an area of an area corresponding to distance d1. In this case, an area remaining after excluding a first image notification 1001 from the display 130 may be controlled to have no output to be displayed, or controlled to display a dark color like black (or a pre-configured color or an image having a low brightness), whereby a power saving effect can be obtained. According to another example, as shown in part [c] of FIG. 10, when the electronic device 101 forms a folding angle of θ2, the electronic device 101 may output an image notification (e.g., a second image notification 1002) only in an area of an area corresponding to distance d2. Referring to FIG. 10, the image notification output by the electronic device 101 may include a video image reproduced from the first image notification 1001 to the second image notification 1002, and the reproduction speed of the video image may be changed based on a folding angular speed (e.g., a first angular speed w1 or a second angular speed w2) of the electronic device 101.

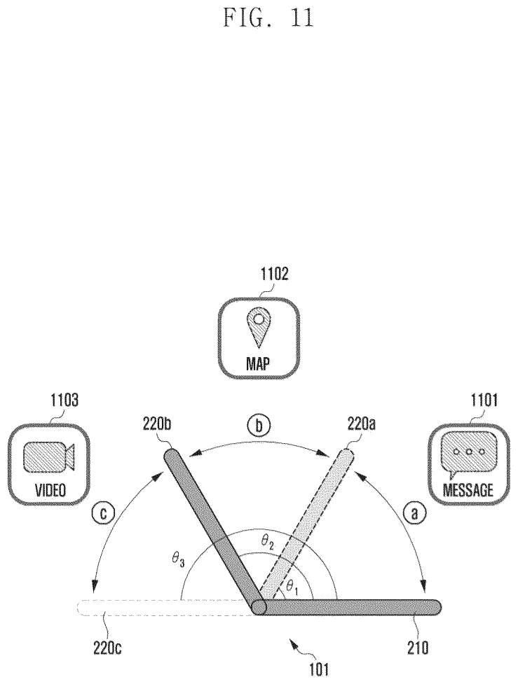

FIG. 11 is an exemplary diagram illustrating outputting a notification based on notification classification information by an electronic device according to various embodiments.

Referring to FIG. 11, with reference to a first housing 210, a second housing 220 may rotate while being connected to the first housing 210, and a folding or unfolding operation of the electronic device 101 may be performed according to the rotation. According to an embodiment, the electronic device 101 may form a folding angle and a folding angular speed according to folding or unfolding. According to an embodiment, the electronic device 101 may identify a folding angle, a folding angular speed, and/or a folding angle interval to which the folding angel belongs, and may acquire folding information. Referring to FIG. 11, the electronic device 101 may form three types of folding angle intervals. A folding angle interval of FIG. 11 is an example, and the areas and the number of folding angle intervals which can be formed by the electronic device 101 are not limited. Referring to FIG. 11, the folding angle of the electronic device 101 may correspond to an angle between the first housing 210 and the second housing 220, and the folding angle interval may be understood as an area to which the folding angle belongs. For example, as shown in FIG. 11, the folding angle interval may include interval \textcircled{a}, interval \textcircled{b}, and interval \textcircled{c}. In this case, interval \textcircled{a} may include an interval in which a folding angle of 0 to θ1 degrees is formed, interval \textcircled{b} may include an interval in which a folding angle of θ1 to θ2 degrees is formed, and interval \textcircled{c} may include an interval in which a folding angle of θ2 to θ3 degrees is formed.

Referring to FIG. 11, the electronic device 101 may output a multimedia notification based on notification classification information. The notification classification information may be information on classification of generated notifications according to an application and/or a function of the electronic device 101. According to an embodiment, a notification generated in the electronic device 101 may be classified according to the type of an application and/or a function corresponding to the generated notification. For example, as shown in FIG. 11, a first notification 1101, a second notification 1102, and a third notification 1103 may be classified as types of corresponding applications and/or functions, i.e., a message, a map, and a video, respectively. According to an embodiment, the notification classification information may include information on the type of an application and/or a function. According to an embodiment, the notification classification information may include priority information. For example, the electronic device 101 may sequentially output the first notification 1101, the second notification 1102, and the third notification 1103 as the electronic device 101 is unfolded. In this case, the electronic device 101 may determine the output order of the first notification 1101, the second notification 1102, and the third notification 1103, based on priority information. The priority information may include information on a priority determined based on the type of an application and/or a function, or a priority that contact information has if the application and/or the function is based on contact information stored in the electronic device 101. For example, if the folding angle interval is interval \textcircled{a}, a message of a pre-determined social media may be displayed, and if there are multiple new messages to be displayed through notifications, priorities of notification display may be designated with reference to a contact (or a transmission counterpart), a message reception order, etc. according to a configuration of a user or a use context in the electronic device 101. According to an embodiment, the notification classification information may include information on a multimedia notification. For example, the notification classification information may include information on the type (e.g., voice, haptic, or image) of a notification.

According to various embodiments, the electronic device 101 may output a multimedia notification, based on folding information and notification classification information. According to an embodiment, the electronic device 101 may store mapping information obtained by mapping the folding information to the notification classification information, and output a notification based on the mapping information. According to an embodiment, the electronic device 101 may store information in which a notification corresponding to the folding information and the notification classification information is configured. The electronic device 101 may output a notification based on the folding information and the notification classification information.

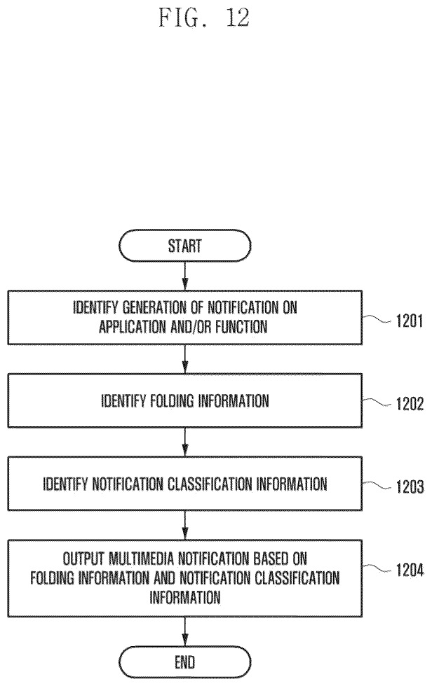

FIG. 12 is a flow chart illustrating an operation of outputting a notification based on notification classification information by an electronic device according to various embodiments.

Referring to FIG. 12, an operation of outputting a notification based on folding information by an electronic device (e.g., the electronic device 101 of FIG. 1 or FIG. 5) may be understood as a series of operations performed by a processor (e.g., the processor 120 of FIG. 1 or FIG. 5) of the electronic device 101. All or some of the respective operations of FIG. 12 may be changed to and/or substituted with other operations, and the order thereof may be changed.

Referring to operation 1201, the processor 120 may identify a notification generated according to an application and/or a function that is being executed. According to an embodiment, when a notification is generated during the execution of the application and/or function, the processor 120 may identify the generated notification.

Referring to operation 1202, the processor 120 may identify folding information. The folding information may be understood as information indicating a folding or unfolding state of the electronic device 101. According to an embodiment, the folding information may include at least a part of information on a folding angle, a folding angular speed, and a folding angle interval. The folding angle interval may be understood as information on an angle interval to which a folding angle formed in real time by the electronic device belongs. According to an embodiment, the processor 120 may identify, in real time, at least one of the folding angle, the folding angular speed, and the folding angle interval, based on the posture formed by a first housing (e.g., the first housing 210 of FIG. 2) and a second housing (e.g., the second housing 220 of FIG. 2), and may acquire the folding information on at least one of the folding angle, the folding angular speed, and the folding interval information.

Referring to operation 1203, the processor 120 may identify notification classification information. The notification classification information may be information on classification of generated notifications according to an application and/or a function of the electronic device 101. According to an embodiment, a notification generated in the electronic device 101 may be classified according to the type of an application and/or a function corresponding to the generated notification. For example, one or more notifications may be classified based on types of applications and/or functions having generated the notifications. According to an embodiment, the notification classification information may include information on the type of an application and/or a function. According to an embodiment, the notification classification information may include priority information. For example, the processor 120 may sequentially output multiple notifications as the electronic device 101 is unfolded or folded. In this case, the processor 120 may determine the output order of the multiple notifications, based on priority information. The priority information may include information on a priority determined based on the type of an application and/or a function, or a priority that contact information has if the application and/or the function is based on contact information stored in the electronic device 101. According to an embodiment, the notification classification information may include information on a multimedia notification. For example, the notification classification information may include information on the type (e.g., voice, haptic, or image) of a notification.

Referring to operation 1204, the processor 120 may output a multimedia notification, based on folding information and notification classification information. According to an embodiment, the processor 120 may store mapping information obtained by mapping the folding information to the notification classification information, and output a notification based on the mapping information. According to an embodiment, the processor 120 may store information in which a notification corresponding to the folding information and the notification classification information is configured. The processor 120 may output a notification based on the folding information and the notification classification information.

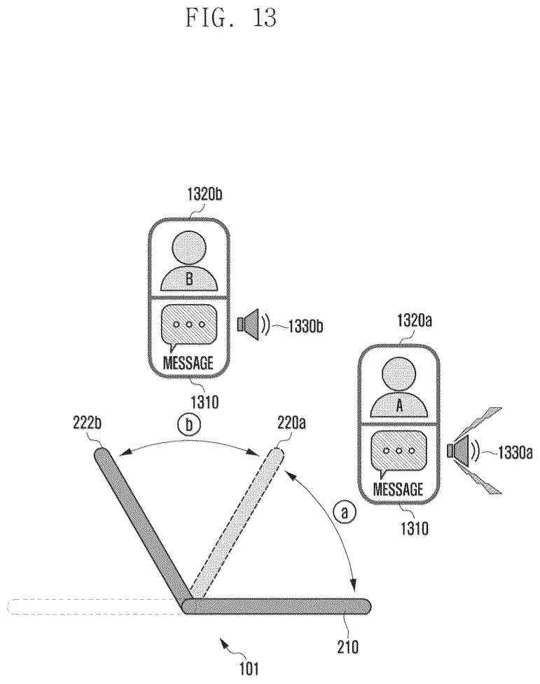

FIG. 13 illustrates contact priority information of notification information according to various embodiments.

Referring to FIG. 13, a notification generated in the electronic device 101 may be a notification related to contact information according to an application and/or a function having caused the generation of the notification. For example, as shown in messages 1310 of FIG. 13, a case of a notification received based on information on different contacts (e.g., contact A or contact B) may be illustrated even for notifications on the same application or function. In this case, the electronic device 101 may output different notifications (e.g., a first multimedia notification 1330a or a second multimedia notification 1330b) based on contact information.

According to an embodiment, the notification classification information may include priority information. If the application and/or the function is based on contact information stored in the electronic device 101, the priority information may include information on a priority that the contact information has. Referring to FIG. 13, contact A and contact B may include different contact priority information pieces from each other. For example, the contact priority information may be pre-configured within a function of the message 1310 of FIG. 13, or may be determined based on contact information pre-stored in another application stored in the electronic device 101.

According to various embodiments, the electronic device 101 may output a multimedia notification based on folding information and notification classification information (e.g., contact priority information). According to an embodiment, the electronic device 101 may store mapping information obtained by mapping the folding information to the notification classification information, and may output the notification based on the mapping information. According to an embodiment, the electronic device 101 may store information in which a notification corresponding to the folding information and the notification classification information is configured. The electronic device 101 may output the notification based on the folding information and the notification classification information. Referring to FIG. 13, the electronic device 101 may be in a state in which the priority of contact A is configured to be higher than the priority of contact B. When the electronic device 101 is unfolded, the electronic device 101 may output a multimedia notification (e.g., a first multimedia notification 1330a) for contact A in interval \textcircled{a} corresponding to a more preceding folding angle interval, and may output a multimedia notification (e.g., a second multimedia notification 1330b) for contact B in interval \textcircled{b} corresponding to a subsequent folding angle interval, based on the identified notification classification information and folding information. In another example, the electronic device 101 may map contact priority information to each of the folding information pieces (e.g., interval \textcircled{a} and interval \textcircled{b}) and store the same. In this case, if information of a higher priority is mapped to interval \textcircled{a}, the electronic device may output a notification (e.g., a first multimedia notification) corresponding to contact A corresponding to interval \textcircled{a} among multiple generated notifications.

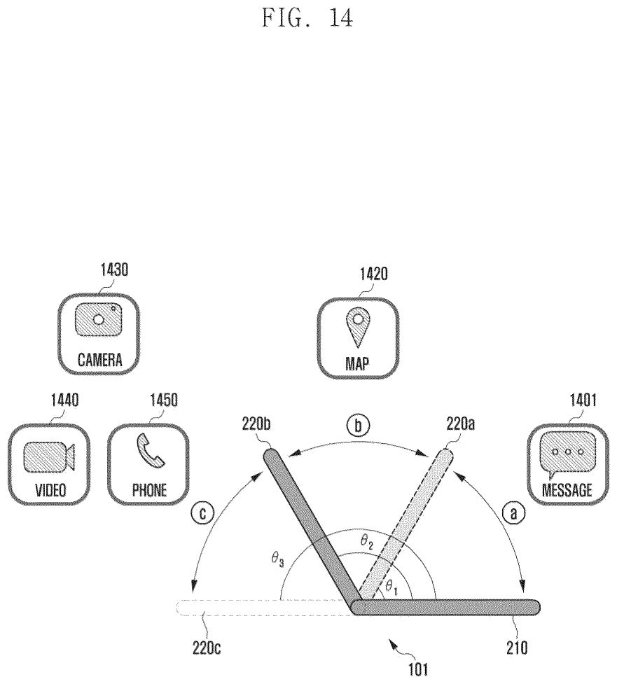

FIG. 14 illustrates application priority information of notification classification information according to various embodiments.

Referring to FIG. 14, the electronic device 101 may identify notification classification information. The notification classification information may be information of classification of generated notifications according to an application and/or a function of the electronic device 101. According to an embodiment, a notification generated in the electronic device 101 may be classified according to the type of an application and/or a function corresponding to the generated notification. For example, one or more notifications may be classified based on types of applications and/or functions having generated the notifications. According to an embodiment, the notification classification information may include information on the type of an application and/or a function. Referring to FIG. 14, respective notifications (e.g., a first notification 1410 to a fifth notification 1450) may be classified according to the corresponding applications and/or functions, i.e., “message”, “map”, “camera”, “video”, and “phone”.

According to various embodiments, the notification classification information may include priority information. For example, the electronic device 101 may sequentially output multiple notifications as the electronic device 101 is unfolded or folded. In this case, the electronic device 101 may determine the output order of the multiple notifications, based on the priority information. The priority information may include a priority determined based on the type of the application and/or function.

Referring to FIG. 14, the multiple notifications may be mapped to the folding information, based on the priorities. For example, a first priority, a second priority, and a third priority may be configured for a first notification 1410, a second notification 1420, and a third notification 1430, respectively, based on the respective corresponding applications and/or functions (e.g., message, map, and camera). In this case, the first notification 1410, the second notification 1420, and the third notification 1430 may be mapped to interval \textcircled{a}, interval \textcircled{b}, and interval \textcircled{c}, respectively.

Referring to FIG. 14, in a case of the same folding information, for example, in a case of interval \textcircled{c} among folding angle intervals, corresponding multiple overlapping notifications (e.g., a third notification 1430, a fourth notification 1140, and a fifth notification 1450) may be generated. In this case, one notification may be selected from among the multiple notifications (e.g., the third notification 1430, the fourth notification 1440, and the fifth notification 1450), based on a priority configured for the corresponding application and/or function, and the one selected notification may be output when the folding information corresponding to interval \textcircled{c}.

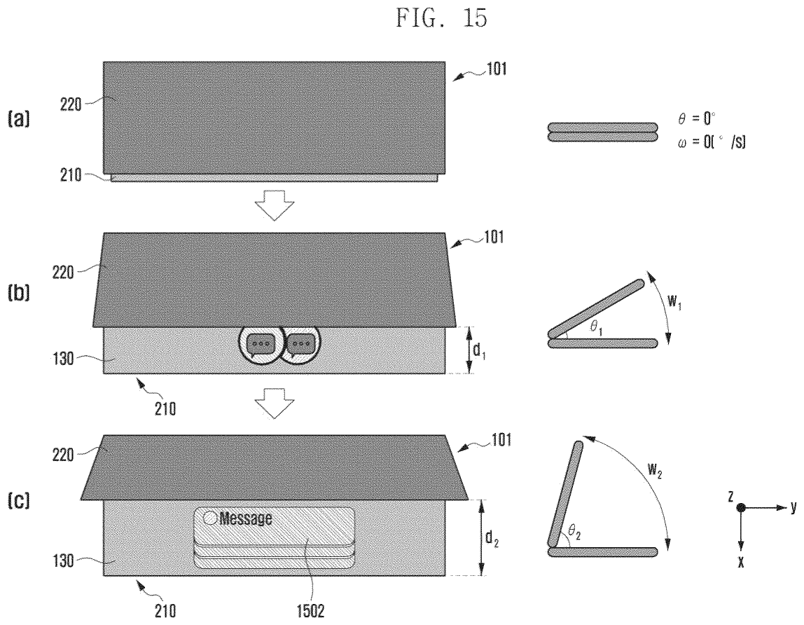

FIG. 15 is an exemplary diagram illustrating changing of a notification, based on folding information, and outputting a notification, based on notification classification information according to various embodiments.

Referring to FIG. 15, a case where a notification according to a message function is generated may be illustrated.

Referring to FIG. 15, the electronic device 101 may identify folding information. The folding information may be understood as information indicating a folding or unfolding state of the electronic device 101. According to an embodiment, the folding information may include at least a part of information on a folding angle (e.g., a first folding angle θ1 or a second folding angle θ2), a folding angular speed (e.g., a first folding angular speed w1 or a second folding angular speed w2), and a folding angle interval. The folding angle interval may be understood as information on an angle interval to which a folding angle formed in real time by the electronic device belongs. According to an embodiment, the processor 120 may identify, in real time, at least one of the folding angle, the folding angular speed, and the folding angle interval, based on the posture formed by a first housing (e.g., the first housing 210 of FIG. 2) and a second housing (e.g., the second housing of FIG. 2), and may acquire folding information on at least one of the folding angle, the folding angular speed, the folding angle interval.

According to various embodiments, the electronic device 101 may identify notification classification information. The notification classification information may include information on a multimedia notification. For example, the notification classification information may include information on the type of a notification (e.g., voice, haptic, or image). Referring to FIG. 15, the notification classification information may include information indicating that a notification of a “message” function corresponds to an image notification. Referring to FIG. 15, the electronic device 101 may output a first notification 1501 or a second notification 1502 corresponding to the “message” function, based on the notification classification information.

According to various embodiments, the electronic device 101 may output a multimedia notification based on folding information and notification classification information. According to an embodiment, the electronic device 101 may store mapping information obtained by mapping the folding information to the notification classification information, and may output a notification based on the mapping information. According to an embodiment, the electronic device 101 may store information in which a notification corresponding to the folding information and the notification classification information is configured. The electronic device 101 may output a notification based on the folding information and the notification classification information.

According to various embodiments, the electronic device 101 may change the multimedia notification, based on the folding information. According to an embodiment, the electronic device 101 may pre-store information on a multimedia notification corresponding to the folding information. For example, the electronic device 101 may pre-store information on a sound notification corresponding to the folding information, i.e., information on at least one of a note, a tempo, and a note order corresponding to the folding information. In another example, the electronic device 101 may pre-store information on a haptic notification corresponding to the folding information, i.e., information on at least one of a vibration strength, a speed, and a duration corresponding to the folding information. In another example, the electronic device 101 may pre-store information on an image notification corresponding to the folding information, i.e., information on at least one of an image area and an image reproduction speed corresponding to the folding information.

According to various embodiments, the electronic device 101 may change an image notification, based on the folding information. According to an embodiment, the electronic device 101 may pre-store information on an image output as an image notification, and/or information on an output area of an image notification. According to an embodiment, the image notification may include a video image. The electronic device 101 may pre-store information on a reproduction area and/or a reproduction speed on the video image. The electronic device 101 may determine an area for output of the image notification, based on the folding information. For example, areas on the display 130 which can be visually identified by a user may vary according to a folding angle formed by the electronic device 101. For example, as shown in part [b] of FIG. 15, when the electronic device 101 forms a folding angle of θ1, the electronic device 101 may output an image notification (e.g., a first image notification 1501) only in an area of an area corresponding to distance d1. In another example, as shown in part [c] of FIG. 15, when the electronic device 101 forms a folding angle of θ2, the electronic device 101 may output an image notification (e.g., a second image notification 1502) only in an area of an area corresponding to distance d2. When the folding angle is changed from 01 to 02, the electronic device 101 may change the shape of the first notification 1501 to the shape of the second notification 1502, based on the folding angle.

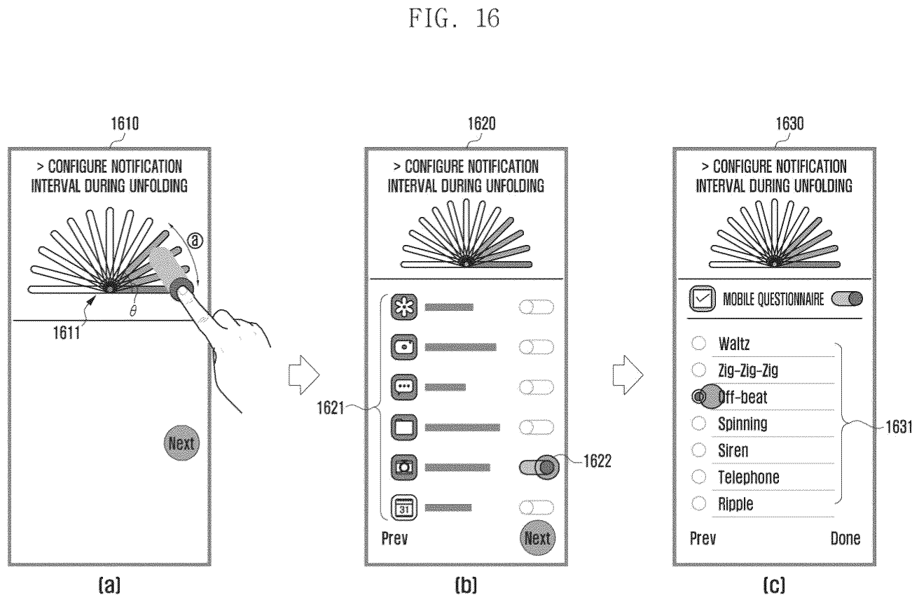

FIG. 16 illustrates a user interface for configuring a multimedia notification, based on folding information and notification classification information according to various embodiments.

Referring to FIG. 16, a user interface for configuring a multimedia notification may include a first interface 1610 for configuring folding information, a second interface 1620 for configuring notification classification information, and a third interface 1630 for configuring a multimedia notification type.

According to an embodiment, the first interface 1610 may include a graphic interface 1611 illustrating a folding operation of the electronic device 101 in a diagram. According to an embodiment, the electronic device 101 may receive an input to the folding information by using the first interface 1610. The first interface 1610 may receive a touch on and/or a drag input to each interval on a graphic interface 1611, so as to configure a folding angle and/or a folding angle interval. Alternatively, an input for configuring a folding angular speed may be received through an additional input.

According to an embodiment, the second interface 1620 may include multiple icons 1621 on multiple applications and/or functions stored in the electronic device 101, and may include a graphic interface such as a toggle switch 1622 so as to configure notification classification information, like application and/or function activation and priority configuration. According to an embodiment, the folding information configured in the first interface 1610 and the notification classification information configured in the second interface 1620 may be mapped to correspond to each other.

According to an embodiment, the electronic device 101 may receive an input for configuring a multimedia notification through the third interface 1630. For example, the third interface 1630 may include a switch button and list 1631 for allowing an application (e.g., “mobile questionnaire”) selected through the second interface 1620 and a multimedia notification (e.g., “off-beat”) to be output to correspond to folding information (e.g., interval \textcircled{a}) selected through the first interface 1610 to be selected.

According to an embodiment, the electronic device 101 may pre-store folding information, notification classification information, and/or information on a multimedia notification, which are received through user interfaces (e.g., the first interface 1610, the second interface 1620, and the third interface 1630) for configuring the multimedia notification.

An electronic device according to various embodiments of the disclosure may include a housing structure including a hinge, a first housing connected to the hinge and including a first surface and a second surface oriented in a direction opposite to the first surface, and a second housing connected to the hinge and including a third surface and a fourth surface oriented in a direction opposite to the third surface, the first surface facing the third surface in a folded state and the first surface and the third surface being oriented in an identical direction in an unfolded state, a first display disposed over the first surface and the third surface, a sensor module, and a processor operatively connected to the sensor module, wherein the processor is configured to detect an unfolding operation or a folding operation of the first housing and the second housing through the sensor module, acquire folding information of the unfolding operation or the folding operation, based on a folding angle formed by the first housing and the second housing in case that the unfolding operation or the folding operation is detected, and output a multimedia notification based on the folding information.

In addition, the folding information may include at least one of a size of the folding angle, an angle interval to which the folding angle belongs, and a folding angular speed corresponding to an angular speed of the folding angle.

In addition, the multimedia notification may include a sound notification, wherein the processor is configured to output, through the sound notification, a sound including a note corresponding to an angle interval in which the folding angle is included.

In addition, the processor may be configured to output, through the sound notification, the corresponding note at a tempo corresponding to an angular speed at which the folding angle changes.

In addition, the processor may be configured to determine an output order of a note included in the sound notification, based on a direction in which the folding angle changes.

In addition, the multimedia notification may include an image output through the first display, wherein the processor is configured to output the image to at least partial area of the first display including an area corresponding to a size of the folding angle.

In addition, the image may include a video image, wherein the processor is configured to output the video image at a speed corresponding to an angular speed of the folding angle.

In addition, the multimedia notification may include a haptic notification including a vibration output, wherein the processor is configured to change at least one of a strength, a speed, and a duration of the vibration output, based on the folding information.

In addition, the processor may be configured to identify whether a notification of an application and/or a function is generated, identify the folding information in case that the notification is generated, identify notification classification information of the generated notification, and output the multimedia notification based on the folding information and the notification classification information.

In addition, the notification classification information may include at least one of a type, priority information, and contact priority information of the application and/or the function.

In addition, the multimedia notification may include at least one of a haptic notification, a sound notification, and an image notification pre-stored to correspond to the application and/or the function, wherein the processor is configured to change the multimedia notification, based on at least one of the folding information and the notification classification information.

A method for outputting a multimedia notification by an electronic device including a first housing and a second housing connected to be mutually folded or unfolded according to various embodiments of the disclosure may include detecting an unfolding operation or a folding operation of the first housing and the second housing, acquiring folding information of the unfolding operation or the folding operation, based on a folding angle formed by the first housing and the second housing in case that the unfolding operation or the folding operation is detected, and outputting a multimedia notification based on the folding information.

In addition, the folding information may include at least one of a size of the folding angle, an angle interval to which the folding angle belongs, and a folding angular speed corresponding to an angular speed of the folding angle.

In addition, the multimedia notification may include a sound notification, and the method may include outputting, through a sound notification, a sound including a note corresponding to an angle interval in which the folding angle is included may be included.

In addition, the method may include determining an output order of a note included in the sound notification, based on a direction in which the folding angle changes.

In addition, the multimedia notification may include an image output through the first display, and the method may include outputting the image to an area including an area corresponding to a size of the folding angle.

In addition, the multimedia notification may include a haptic notification including a vibration output, and the method may include changing at least one of a strength, a speed, and a duration of the vibration output, based on the folding information.

In addition, the method may include identifying whether a notification of an application and/or a function is generated, identifying the folding information in case that the notification is generated, identifying notification classification information of the generated notification, and outputting the multimedia notification based on the folding information and the notification classification information.

In addition, the notification classification information may include at least one of a type, priority information, and contact priority information of the application and/or the function.

In addition, the notification classification may include at least one of a haptic notification, a sound notification, and an image notification pre-stored to correspond to the application and/or the function, and the method may include changing the multimedia notification, based on at least one of the folding information and the notification classification information.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device comprising:
a housing structure comprising:
a hinge;
a first housing connected to the hinge;
a first surface and a second surface oriented in a direction opposite to the first surface;
a second housing connected to the hinge, the second housing comprising a third surface and a fourth surface oriented in a direction opposite to the third surface, the first surface facing the third surface in a folded state, and the first surface and the third surface being oriented in a same direction in an unfolded state;
a first display provided over the first surface and the third surface;
a sensor; and
a processor operatively connected to the sensor,
wherein the processor is configured to:
detect an unfolding operation or a folding operation of the first housing and the second housing through the sensor;
based on the unfolding operation or the folding operation being detected, acquire folding information of the unfolding operation or the folding operation, based on a folding angle formed by the first housing and the second housing; and
provide a multimedia notification based on the folding information.

2. The electronic device of claim 1, wherein the folding information comprises at least one of a size of the folding angle, an angle interval in which the folding angle is included, or a folding angular speed corresponding to an angular speed of the folding angle.

3. The electronic device of claim 1, wherein the multimedia notification comprises a sound notification, and
wherein the processor is further configured to provide, through the sound notification, a sound comprising a note corresponding to an angle interval in which the folding angle is included.

4. The electronic device of claim 3, wherein the processor is further configured to provide, through the sound notification, the corresponding note at a tempo corresponding to an angular speed at which the folding angle changes.

5. The electronic device of claim 3, wherein the processor is further configured to identify an output order of a note included in the sound notification, based on a direction in which the folding angle changes.

6. The electronic device of claim 1, wherein the multimedia notification comprises an image provided through the first display, and
wherein the processor is further configured to provide the image to at least a partial area of the first display comprising an area corresponding to a size of the folding angle.

7. The electronic device of claim 6, wherein the image comprises a video image, and
wherein the processor is further configured to provide the video image at a speed corresponding to an angular speed of the folding angle.

8. The electronic device of claim 1, wherein the multimedia notification comprises a haptic notification comprising a vibration output, and
wherein the processor is further configured to change at least one of a strength, a speed, or a duration of the vibration output, based on the folding information.

9. The electronic device of claim 1, wherein the processor is further configured to:
identify whether a notification of an application or a function is generated;
based on the notification being generated, identify the folding information;
identify notification classification information of the generated notification; and
provide the multimedia notification based on the folding information and the notification classification information.

10. The electronic device of claim 9, wherein the notification classification information comprises at least one of a type, priority information, or contact priority information of the application or the function.

11. The electronic device of claim 9, wherein the multimedia notification comprises at least one of a haptic notification, a sound notification, or an image notification pre-stored to correspond to the application or the function, and
wherein the processor is further configured to change the multimedia notification, based on at least one of the folding information and the notification classification information.

12. A method of providing a multimedia notification by an electronic device comprising a first housing and a second housing connected to be mutually folded or unfolded, the method comprising:
detecting an unfolding operation or a folding operation of the first housing and the second housing;
based on the unfolding operation or the folding operation being detected, acquiring folding information of the unfolding operation or the folding operation, based on a folding angle formed by the first housing and the second housing; and
providing a multimedia notification based on the folding information.

13. The method of claim 12, wherein the folding information comprises at least one of a size of the folding angle, an angle interval in which the folding angle is included, or a folding angular speed corresponding to an angular speed of the folding angle.

14. The method of claim 12,
wherein the multimedia notification comprises a sound notification, and
wherein providing of the multimedia notification comprises providing, through the sound notification, a sound comprising a note corresponding to an angle interval in which the folding angle is included.

15. The method of claim 14, the method further comprising identifying an output order of a note included in the sound notification, based on a direction in which the folding angle changes.

16. The method of claim 12, wherein the multimedia notification comprises an image provided through the first display, and
wherein providing of the multimedia notification comprises providing the image to at least a partial area of the first display comprising an area corresponding to a size of the folding angle.

17. The method of claim 12, wherein the image comprises a video image, and
wherein providing of the multimedia notification comprises providing the video image at a speed corresponding to an angular speed of the folding angle.

18. The method of claim 12, comprising:
identifying whether a notification of an application or a function is generated;
based on the notification being generated, identifying the folding information;
identifying notification classification information of the generated notification; and
providing the multimedia notification based on the folding information and the notification classification information.

19. The method of claim 18, wherein the notification classification information comprises at least one of a type, priority information, or contact priority information of the application or the function.

20. The method of claim 18, wherein the multimedia notification comprises at least one of a haptic notification, a sound notification, or an image notification pre-stored to correspond to the application or the function, and
wherein the method further comprises changing the multimedia notification, based on at least one of the folding information and the notification classification information.
